(19) United States
(12) Patent Application Publication
(10) Pub. No.: US 2016/0050785 A1
(43) Pub. Date: Feb. 18, 2016

(54) ELECTRONIC DEVICE WITH SUPPORT

(71) Applicant: TPV-INVENTA Technology Co., Ltd., Taipei (TW)

(72) Inventors: Shih-Yu Hsieh, Taipei (TW); Pei-Ju Tsai, Taipei (TW)

(21) Appl. No.: 14/691,110

(22) Filed: Apr. 20, 2015

(30) Foreign Application Priority Data
Aug. 15, 2014 (TW) 103214667

(51) Int. Cl. H05K 7/00

(52) U.S. Cl. CPC H05K 7/00

(57) ABSTRACT

An electronic device with a support includes a main body and a support arm. The support arm includes a fixed component and a support component. The support component comprises a pivot end and a leaning end. The support component pivots relative to the fixed component, such that the support arm has a first usage state and a second usage state. When in the first usage state, an acute angle is formed between the support component and the fixed component, and the leaning end of the support component and a bottom edge of the main body both support the main body. When in the second usage state, an obtuse angle is formed between the support component and the fixed component, and the leaning end of the support component is assembled with a seat which is for supporting the main body.

### CROSS-REFERENCE TO RELATED APPLICATIONS

This non-provisional application claims priority under 35 U.S.C. §119(a) on Patent Application No(s). 103214667 filed in Taiwan, R.O.C. on Aug. 15, 2014, the entire contents of which are hereby incorporated by reference.

### BACKGROUND

1. Technical Field

The disclosure relates to an electronic device. More particularly, the disclosure relates to an electronic device with a support.

2. Background

With the increasing demands for electronic devices, take display devices for example, usage modes of the display devices can be roughly distinguished into a “picture frame mode” and a “display mode”. The “picture frame mode” means that the display device stands and is directly supported on a table by supports, which prevents the display device from falling over. The “display mode” means that the display device is assembled with a seat or a dock to stand on a table, which is an ordinary way to dispose the display device.

Thus, different types of the supports need to be manufactured for being compatible with different usage modes of the display devices. For example, some supports are manufactured for the “picture frame mode”, and some supports are manufactured for the “display mode”. Accordingly, the addition of the multiple supports increases the total costs of display devices.

### SUMMARY

One aspect of the disclosure provides an electronic device with a support, which comprises a main body and a support arm. The support arm comprises a fixed component and a support component. The fixed component is assembled at a side of the main body. The support component comprises a pivot end and a leaning end. The pivot end is opposite to the leaning end and pivots on the fixed component. The support component pivots relative to the fixed component, such that the support arm has a first usage state and a second usage state. When in the first usage state, an acute angle is formed between the support component and the fixed component, and the leaning end of the support component and a bottom edge of the main body both support the main body. When in the second usage state, an obtuse angle is formed between the support component and the fixed component, and the leaning end of the support component is assembled with a seat which is for supporting the main body.

### BRIEF DESCRIPTION OF THE DRAWINGS

The disclosure will become more fully understood from the detailed description given herein-below and the accompanying drawings which are given by way of illustration only and thus are not limitative of the disclosure, and wherein:

FIG. 1A is an exploded view of an electronic device with a support in a first usage state according to an embodiment of the disclosure;

FIG. 1B is a schematic perspective view of the electronic device with the support in FIG. 1A;

FIG. 1C is an exploded view of the electronic device with the support in a second usage state in FIG. 1A;

FIG. 1D is a schematic perspective view of the electronic device with the support in FIG. 1C;

FIG. 2A is an exploded view of an electronic device with a support in a first usage state according to another embodiment of the disclosure;

FIG. 2B is a schematic perspective view of the electronic device with the support in FIG. 2A;

FIG. 2C is an exploded view of the electronic device with the support in a second usage state in FIG. 2A; and

FIG. 2D is a schematic perspective view of the electronic device with the support in FIG. 2C.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawings.

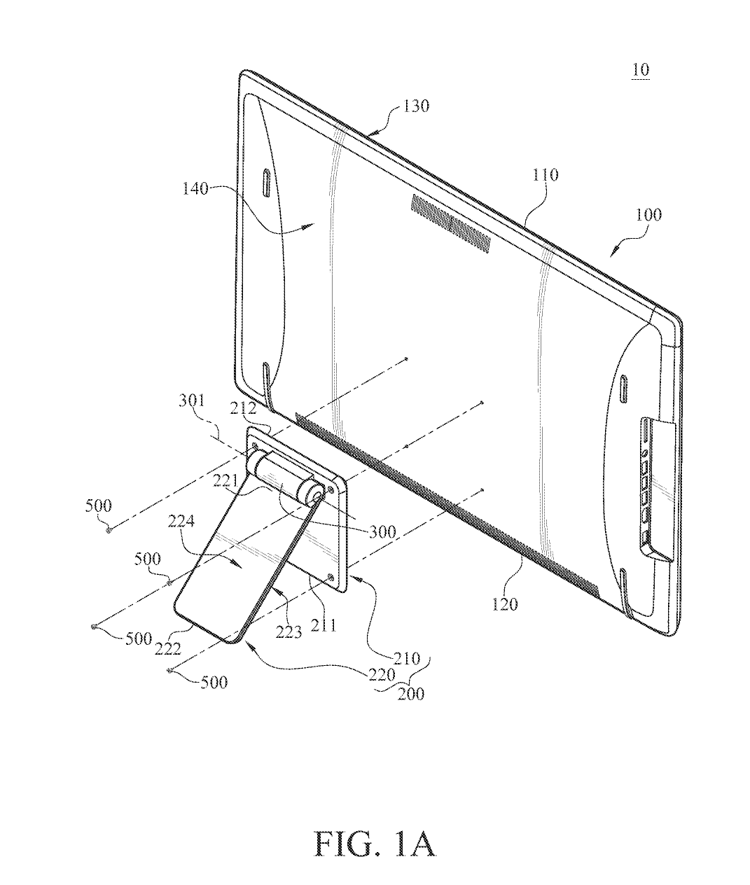

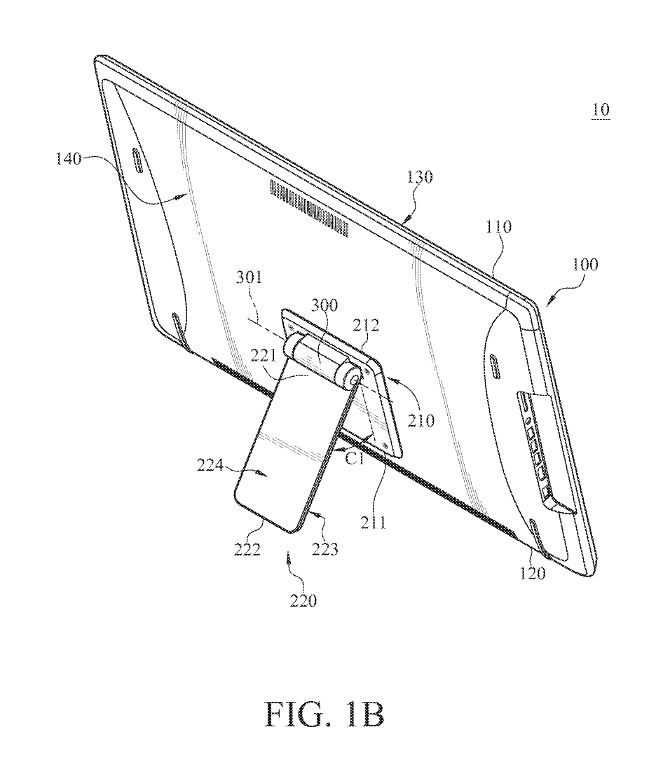

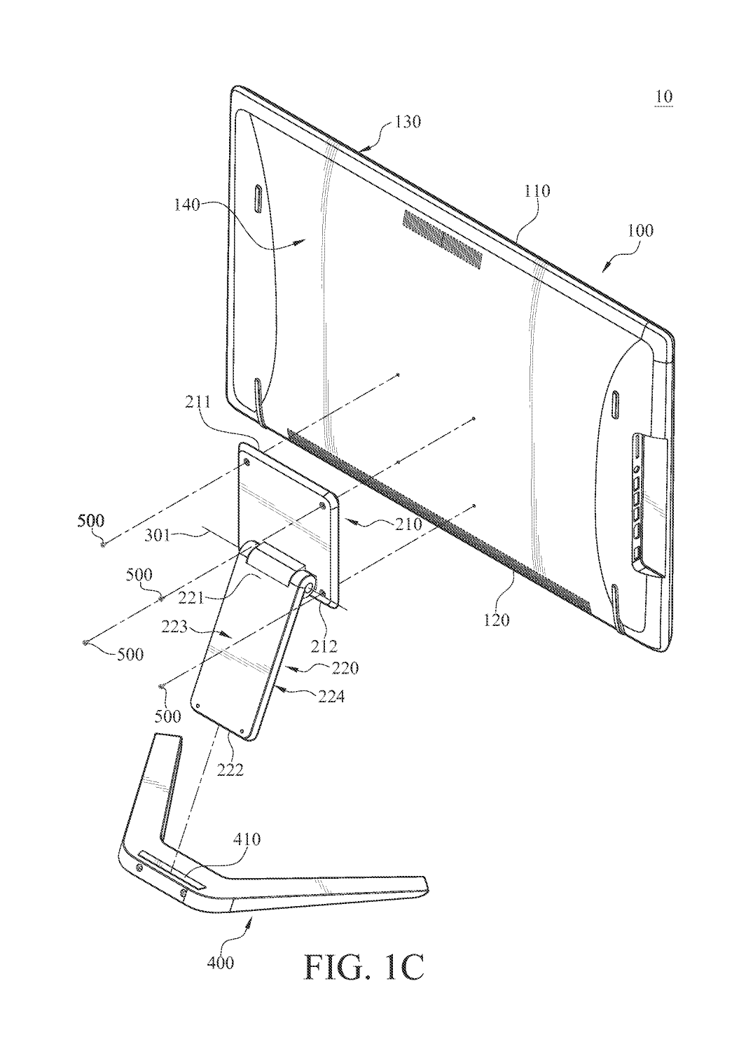

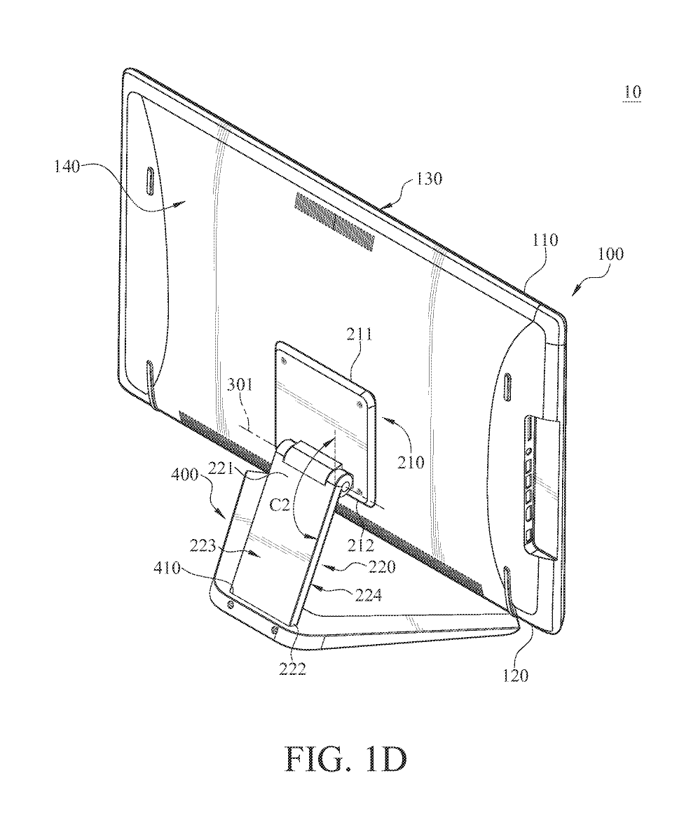

Please refer to FIG. 1A through FIG. 1D. FIG. 1A is an exploded view of an electronic device with a support in a first usage state according to an embodiment of the disclosure. FIG. 1B is a schematic perspective view of the electronic device with the support in FIG. 1A. FIG. 1C is an exploded view of the electronic device with the support in a second usage state in FIG. 1A. FIG. 1D is a schematic perspective view of the electronic device with the support in FIG. 1C. In this embodiment, the electronic device 10 with the support is a display screen (namely, monitor or display device). However, the electronic device 10 with the support is not limited to a display screen.

The electronic device 10 with the support comprises a main body 100 and a support arm 200. In this and some embodiments, the electronic device 10 with the support further comprises a hinge 300. However, the disclosure is not limited to comprise a hinge 300. The main body 100 has a top edge 110 and a bottom edge 120 which are opposite to each other. In this embodiment the top edge 110 is substantially parallel to the bottom edge 120.

In this embodiment, the main body 100 comprises a display surface 130 and a rear surface 140 which are opposite to each other. The display surface 130 is a surface having a display of the electronic device 10 (display screen). The rear surface 140 is opposite to the display surface 130. As shown in FIG. 1A and FIG. 1C, the top edge 110 is an upper side edge of the display surface 130 (and the rear surface 140), and the bottom edge 120 is a bottom side edge of the display surface 130 (and the rear surface 140).

The support arm 200 is for supporting the main body 100. When the electronic device 10 is put on a table and operated by a user, the support arm 200 prevents the main body 100 from falling over. Additionally, the support arm 200 comprises a fixed component 210 and a support component 220. The fixed component 210 is assembled with the rear surface 140 of the main body 100. In other words, the fixed component 210 is disposed at a side of the main body 100 which is opposite to the display surface 130. Furthermore, a first end 211 and a second end 212 are defined as two ends of the fixed component 210 which are opposite to each other. The first end 211 and the second end 212 will be described specifically hereinafter with reference to the operation of the electronic device 10.

Moreover, the support component 220 comprises a pivot end 221 and a leaning end 222 that is opposite to the pivot end 221. The pivot end 221 is for pivoting on the fixed component 210 via the hinge 300. More particularly, a side of the hinge 300 is connected to the fixed component 210, and the other side of the hinge 300 is connected to the pivot end 221 of the support component 220. Accordingly, the pivot end 221 is for rotating relative to the fixed component 210. Moreover, a first surface 223 and a second surface 224 are defined as two surfaces of the support component 220 which are opposite to each other. The first surface 223 and the second surface 224 will be described specifically hereinafter with reference to the operation of the electronic device 10.

In this embodiment, the hinge 300 is a damping hinge. However, the hinge 300 is not limited to a damping hinge. Additionally, a pivot axis 301 of the hinge 300 is defined as the center of rotations of the pivot end 221 and the fixed component 210, such that the pivot end 221 and the fixed component 210 are for pivoting about the pivot axis 301. In this embodiment, the pivot axis 301 is substantially parallel to the top edge 110 and the bottom edge 120.

In this and some embodiments, the electronic device 10 further comprises a seat 400 with a slot 410. The leaning end 222 of the support component 220 is selectively inserted into the slot 410 of the seat 400

In this and some embodiments, the electronic device 10 further comprises at least one affixing component 500 for affixing the fixed component 210 to the main body 100. In this embodiment, the quantity of the affixing components 500 is four. However, the quantity of the affixing component 500 is not limited to four. For example, the quantity of the affixing component 500 is one, two, three or more than four.

Two usage states of the electronic device 10 will be described as follows. Please refer to FIG. 1B, when an acute angle C1 is formed between the first surface 223 of the support component 220 and the fixed component 210, the first end 211 of the fixed component 210 is closer to the bottom edge 120 than the second end 212, and the first surface 223 of the support component 220 is facing to the rear surface 140 of the main body 100. At this time, the electronic device 10 with the support is in a first usage state. When the electronic device 10 is in the first usage state, the user can put the electronic device 10 with the support on the table, and the leaning end 222 of the support component 220 and the bottom edge 120 both support the electronic device 10 with the support. The first usage state herein is defined as a “picture frame mode”.

Please refer to FIG. 1D, when the user rotate the support component 220 relative to the fixed component 210 to form an obtuse angle C2 between the first surface 223 of the support component 220 and the fixed component 210, the second end 212 of the fixed component 210 is closer to the bottom edge 120 and the second surface 224 of the support component 220 is facing to the rear surface 140 of the main body 100. At this time, the electronic device 10 with the support is in a second usage state. When the electronic device 10 with the support is in the second usage state, the user can insert the leaning end 222 of the support component 220 into the slot 410 of the seat 400, such that the seat 400 is for supporting the electronic device 10 with the support. The second usage state herein is defined as a “display mode”.

Accordingly, in this embodiment, the electronic device 10 with the support can meet both the “picture frame mode” and the “display mode”. That is to say, the same support is used for different electronic devices. Moreover, the user can select the “picture frame mode” or the “display mode” alternatively according to their preferences.

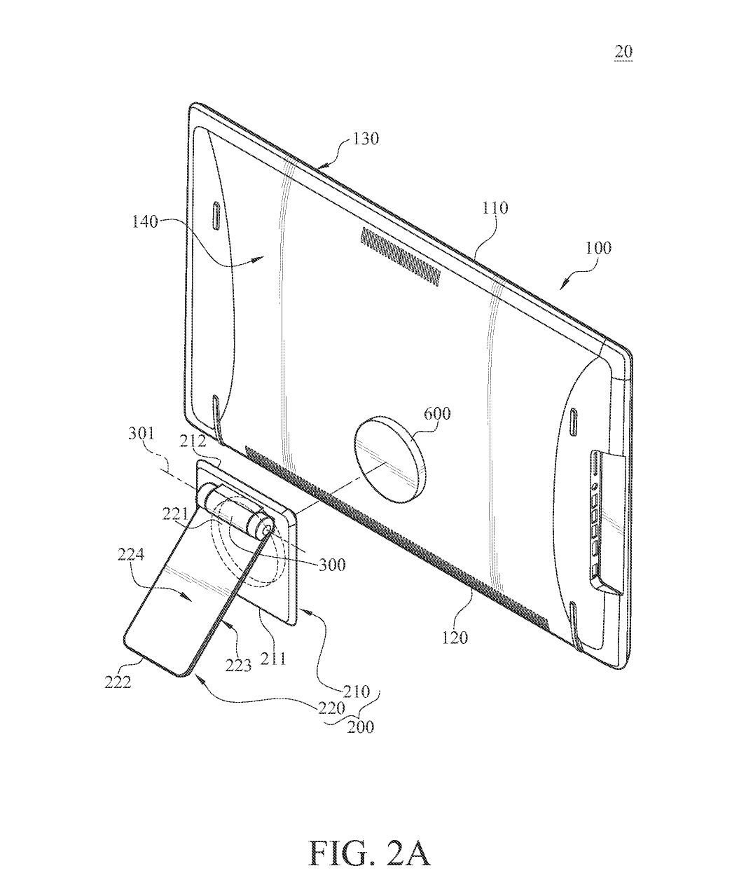

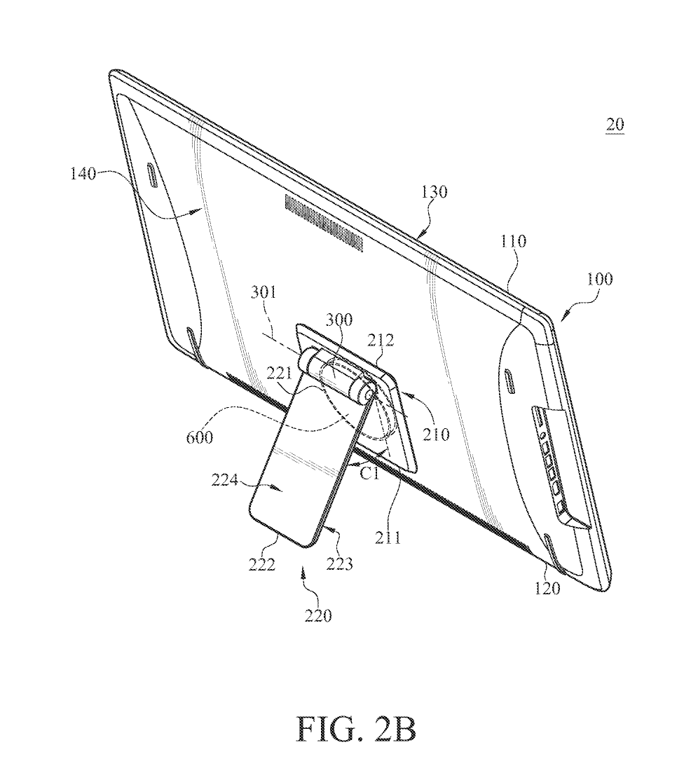

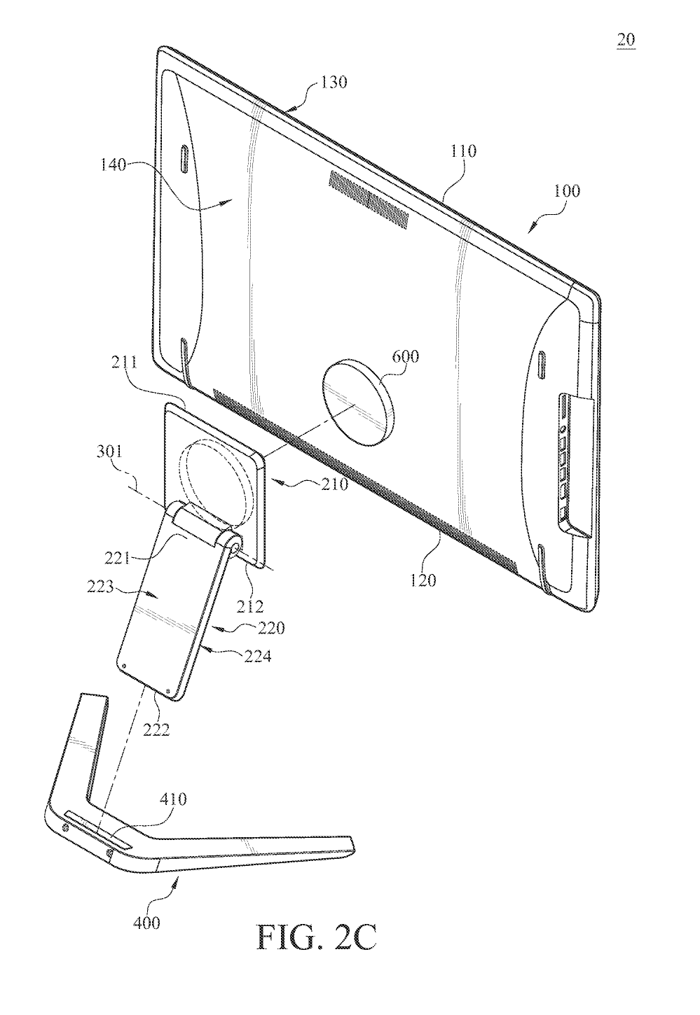

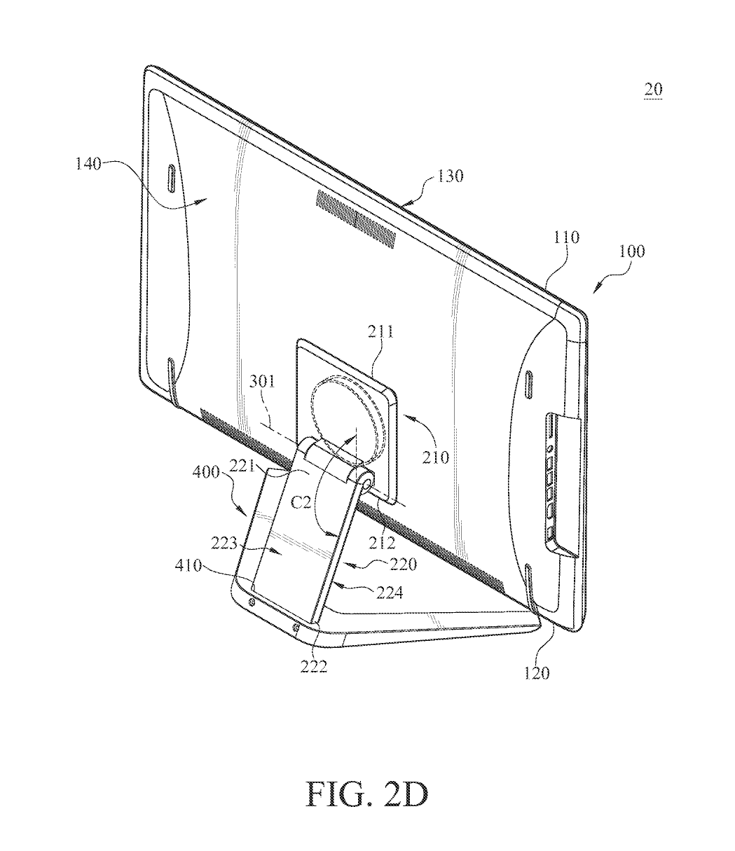

Please refer to FIG. 2A through FIG. 2D. FIG. 2A is an exploded view of an electronic device with a support in a first usage state according to another embodiment of the disclosure. FIG. 2B is a schematic perspective view of the electronic device with the support in FIG. 2A. FIG. 2C is an exploded view of the electronic device with the support in a second usage state in FIG. 2A. FIG. 2D is a schematic perspective view of the electronic device with the support in FIG. 2C.

Since this embodiment is similar to the above mentioned embodiment, only the difference between two embodiments will be described hereinafter.

In this embodiment, an electronic device 20 with a support further comprises a rotating component 600 disposed on the main body 100. The fixed component 210 is rotatably assembled with the rotating component 600, such that the fixed component 210 is for rotating relative to the main body 100. Accordingly, the support arm 200 can be switched to the first usage state (as shown in FIG. 2B) or the second usage state (as shown in FIG. 2D) by rotating the support component 220. In this embodiment, the user can change the usage states of the support arm 200 due to the rotating component 600.

According to the electronic device with the support of the disclosure, the support component is capable of rotating relative to the fixed component, so as to change the usage states of the electronic device with the support. Thus, the electronic device with the support can meet both the “picture frame mode” and the “display mode”. That is to say, one support can be used for different electronic devices, and therefore the electronic device only needs to have one support for being compatible with different usage modes (states).

Furthermore, in some embodiments, the electronic device with the support further comprises the rotating component. Thus, it is convenient for the user to change the usage modes of the support arm due to the rotating component.

The disclosure will become more fully understood from the said embodiment for illustration only and thus does not limit the disclosure. Any modifications within the spirit and category of the disclosure fall in the scope of the disclosure.

What is claimed is:

1. An electronic device with a support, comprising:
a main body; and
a support arm, comprising:
a fixed component assembled at a side of the main body; and
a support component comprising a pivot end and a leaning end, and the pivot end being opposite to the leaning end and pivoting on the fixed component;
wherein, the support component pivots relative to the fixed component, such that the support arm has a first usage state and a second usage state, wherein when in the first usage state, an acute angle is formed between the support component and the fixed component, and the leaning end of the support component and a bottom edge of the main body both support the main body, wherein when in the second usage state, an obtuse angle is formed between the support component and the fixed component, and the leaning end of the support component is assembled with a seat which is for supporting the main body.

2. The electronic device with the support according to claim 1, further comprising a hinge disposed on the fixed component, and the pivot end of the support component for pivoting on the fixed component via the hinge.

3. The electronic device with the support according to claim 2, wherein the main body comprises a top edge, the top edge and the bottom edge are opposite to each other, the hinge comprises a pivot axis, and the pivot axis is substantially parallel to the top edge and the bottom edge of the main body.

4. The electronic device with the support according to claim 3, wherein the hinge is a damping hinge.

5. The electronic device with the support according to claim 4, wherein the seat comprises a slot, and when the support arm is in the second usage state, the leaning end of the support component is inserted into the slot.

6. The electronic device with the support according to claim 5, further comprising at least one affixing component for affixing the fixed component to the main body.

7. The electronic device with the support according to claim 6, wherein the main body comprises a display surface and a rear surface that is opposite to the display surface, and the fixed component of the support arm is disposed at and affixed to the rear surface of the main body.

8. The electronic device with the support according to claim 7, wherein the support component comprises a first surface and a second surface that is opposite to the first surface, when the support arm is in the first usage state, the acute angle is formed between the first surface and the fixed component, and the first surface is facing to the rear surface of the main body.

9. The electronic device with the support according to claim 7, wherein the support component comprises a first surface and a second surface that is opposite to the first surface, when the support arm is in the second usage state, the obtuse angle is formed between the first surface and the fixed component, and the second surface is facing to the rear surface of the main body.

10. The electronic device with the support according to claim 1, further comprising a rotating component disposed on the main body, the fixed component rotatably assembled with the rotating component, such that the fixed component is for rotating relative to the main body.
